(19) United States
(12) Patent Application Publication
(10) Pub. No.: US 2025/0166983 A1
(43) Pub. Date: May 22, 2025

(54) RESIDUAL GAS ANALYSER, PROJECTION EXPOSURE APPARATUS COMPRISING A RESIDUAL GAS ANALYSER AND METHOD OF RESIDUAL GAS ANALYSIS

(71) Applicant: Carl Zeiss SMT GmbH, Oberkochen (DE)

(72) Inventors: Achim SCHOELL, Kitzingen (DE); Thorsten BENTER, Haan (DE); Hendrik KERSTEN, Wuppertal (DE); Kai KROLL, Wuppertal (DE); Marco THINIUS, Wuppertal (DE)

(21) Appl. No.: 19/027,781

(22) Filed: Jan. 17, 2025

Related U.S. Application Data
(63) Continuation of application No. PCT/EP2023/068178, filed on Jul. 3, 2023.

(30) Foreign Application Priority Data
Jul. 18, 2022 (DE) 102022207292.8

(51) Int. Cl. H01J 49/04; G03F 7/00; H01J 49/06; H01J 49/16; H01J 49/40

(52) U.S. Cl. CPC H01J 49/0422; G03F 7/70841; G03F 7/7085; G03F 7/70916; H01J 49/068; H01J 49/168; H01J 49/401

(57) ABSTRACT

This disclosure is directed to a residual gas analyser, in particularly, a residual gas analyser for analysing a residual gas in a microlithography projection exposure apparatus. The residual gas analyser includes a mass spectrometer and an admission device for admitting constituents of the residual gas from a vacuum environment into the mass spectrometer. The admission device includes a switchable ion source. The ion source in a first switching state allows ionized constituents of the residual gas to pass through. The ion source in a second switching state ionizes neutral constituents of the residual gas. The disclosed techniques also relate to a projection exposure apparatus including such a residual gas analyser and to a method of residual gas analysis.

### CROSS-REFERENCE TO RELATED APPLICATION

This is a Continuation of International Application PCT/EP2023/068178, which has an international filing date of Jul. 3, 2023, and the disclosure of which is incorporated in its entirety into the present Continuation by reference. This Continuation also claims foreign priority under 35 U.S.C. § 119 (a)-(d) to and also incorporates by reference, in its entirety, German Patent Applications DE 10 2022 207 292.8 filed on Jul. 18, 2022.

### FIELD

The techniques disclosed herein relate to a residual gas analyser, especially for analysing a residual gas in a microlithography projection exposure apparatus. The disclosed techniques also relate to a projection exposure apparatus including a residual gas analyser and to a method of residual gas analysis.

### BACKGROUND

Microlithography projection exposure apparatuses are utilized for the production of integrated circuits with particularly small structures. A mask ((i.e., a reticle) exposed to very short-wave deep ultraviolet or extreme ultraviolet radiation (DUV or EUV radiation, collective referred to as “very short-wave UV radiation”) is imaged onto a lithography object in order to transfer the mask structure to the lithography object.

The projection exposure apparatus includes multiple mirrors at which the radiation is reflected. The mirrors have a precisely defined shape and are precisely positioned in order that the image of the mask onto the lithography object has sufficient quality.

Because of the low transmittance of all gases for very short-wave UV radiation, the optical elements of such a projection exposure apparatus are operated in a vacuum environment. Interaction of the very short-wave UV radiation with the residual gas in the vacuum environment in the course of operation of the projection exposure apparatus gives rise to ionic, free-radical or neutral (excited) constituents of the residual gas. Knowledge of the composition of this gas or plasma atmosphere is important for the operation of the projection exposure apparatus. If the composition of the residual gas specified in the design of the apparatus is not observed, this can result in degradation effects on the mirrors of the projection exposure apparatus.

The degradation effects arise both from the ionized constituents of the residual gas and from the neutral constituents of the residual gas. With known residual gas analysers, it is not possible to detect both ionized and neutral constituents of residual gas.

### SUMMARY

It is an object of the disclosed techniques to present a residual gas analyser, a projection exposure apparatus and a method of residual gas analysis that avoid these disadvantages.

The disclosed techniques relate to a residual gas analyser, especially for analysing a residual gas in a microlithography projection exposure apparatus. The residual gas analyser includes a mass spectrometer and an admission device for admission of constituents of the residual gas from a vacuum environment into the mass spectrometer. The admission device includes a switchable ion source. The ion source in a first switching state allows ionized constituents of the residual gas to pass through. In a second switching state, the ion source ionizes neutral constituents of the residual gas.

The disclosed techniques are based on the idea of enabling two modes of operation of the residual gas analyser via the switchable ion source. In the first switching state, native ions that are already present as ions in the atmosphere in the vacuum environment can pass through the ion source and be analysed in the mass spectrometer. In the second switching state, ions are generated from neutral particles present in the atmosphere of the vacuum environment and transferred to the mass spectrometer for analysis. By utilizing the two modes of operation, it becomes possible to detect both the ionized and the neutral constituents of the residual gas.

The ion source may include an ionization unit (or ionizer) in which neutral constituents of the residual gas are ionized when the ion source is in the second switching state. In the first switching state of the ion source, the ionization unit may be inactive. The ionization may be based on an electrical interaction between the ionization unit and the constituents of the residual gas. In one embodiment, the ionization is based on electron ionization. The ionization unit may have a filament through which electrical current is passed, such that electrons are knocked out of the filament material. It is possible to apply an electrical field by which the electrons are accelerated and through which the constituents of the residual gas are directed, such that the constituents of the residual gas are ionized by interaction with the electrons.

The ion source may have a multitude of electrodes in order to influence the direction of movement of ions. An electrical voltage, especially an AC voltage, may be applied to the electrodes in order to steer the ions in the direction of the mass spectrometer. The electrodes may be in a peripheral arrangement relative to a central channel of the ion source. Because a central channel is left clear for the passage of constituents of the residual gas, constituents of the residual gas can enter the mass spectrometer through the ion source without any great resistance. The smallest diameter of the channel is preferably larger than 0.5 cm, further preferably larger than 1 cm. The smallest diameter of an ionization volume formed in the ionization unit is preferably at least as large as the smallest diameter of the channel.

The ion source may have a first electrode arrangement and a second electrode arrangement. The first electrode arrangement may be disposed between an inlet opening of the ion source and the ionization unit. The second electrode arrangement may be disposed between the ion source and an outlet opening of the ion source. A thermal insulation may be formed between the ionization unit and the first electrode arrangement and/or between the ionization unit and the second electrode arrangement in order to prevent thermal stress on the electrode arrangements caused by the ionization unit.

The second electrode arrangement may be actuated during operation of the residual gas analyser such that ions are accepted from the region of the ionization unit and directed to the mass spectrometer. The second electrode arrangement may be actuated in the switching state of the ion source with a first electrical signal and actuated in the second switching state of the ion source with a different second electrical signal.

The first and second electrode arrangements may be actuated in the first switching state of the ion source such that the first electrode arrangement and the second electrode arrangement collectively form ion optics for native ions that enter the ion source. The ion optics can direct the ions from the inlet to the outlet of the ion source and direct them across to the mass spectrometer.

In the second switching state, the first and/or second electrode arrangement may be actuated such that native ions are blocked, i.e., stopped from entering the mass spectrometer through the ion source. In this way, the mass spectrometry analysis may be concentrated on those constituents of the residual gas that were initially neutral and were only converted to an ionized state in the ionization unit.

The admission device of the residual gas analyser may include an ion transfer unit (or ion transfer device). The ion transfer unit may be designed to ensure passage of ions onward in the direction of the mass spectrometer without neutralization of the ions by contact with components of the residual gas analyser.

The ion transfer unit may be configured such that ions are passed through the ion transfer unit in the longitudinal direction. The longitudinal direction of the ion transfer unit may correspond to the longitudinal direction of the ion source.

The ion transfer unit may include a pole arrangement composed of a multitude of electrical poles. An electrical alternating field may be applied to the poles, in order to steer the ions onto a pathway in the longitudinal direction of the ion transfer unit. Each pole may be disposed between two adjacent poles having an opposite electrical potential. An RF voltage may be applied to the poles, i.e., an AC voltage in the radiofrequency region. In this way, the pole arrangement may act as ion optics, via which the ions are directed from an inlet end to an outlet end of the ion transfer unit.

The pole arrangement may take the form of a hexapole. The hexapole may extend in longitudinal direction of the ion transfer unit and have six electrical poles distributed over the circumference of the ion transfer unit. The ion transfer unit may consist of a single hexapole that extends over the entire length of the ion transfer unit. Also possible are multiple hexapoles arranged in succession in the longitudinal direction.

The ion transfer unit may be disposed between an inlet opening of the residual gas analyser and the ion source. The ion transfer unit may serve to direct native ions of the residual gas in the direction of the ion source. If the ion source is in the first switching state, the ions conducted out of the ion transfer unit can pass through the ion source and then analysed in the mass spectrometer according to their mass/charge ratio.

There are cases in which the ion source and/or the mass spectrometer cannot be disposed close to the vacuum environment. In order to enable mass spectrometry analysis of the ions at a greater distance from the vacuum environment, it is advantageous when the vacuum transfer unit extends over a distance of at least 20 cm, preferably at least 50 cm, further preferably at least 80 cm. If, in other embodiments, the ion source is disposed close to the vacuum environment, an ion transfer unit between the inlet opening of the residual gas analyser and ion source is dispensable.

An ion decelerator may be disposed between the inlet opening of the residual gas analyser and the ion transfer unit in order to slow down native ions entering the residual gas analyser with an adjustable deceleration voltage. Only those native ions having sufficient kinetic energy on entry into the residual gas analyser to overcome the deceleration voltage contribute to the result of the mass spectrometry analysis. In this way, analysis resolved not only by mass but also by the kinetic energy of the native ions is enabled.

The mass spectrometer may also take the form of a time-of-flight mass analyser (TOF analyser), especially of a time-of-flight mass analyser with an orthogonal acceleration stage. The mass spectrometer may encompass a measurement range of 1 to 500 daltons, preferably 1 to 1000 daltons, such that complete mass spectra can be recorded over this mass range. The recording frequency of the mass spectrometer may be greater than 10 kHz. An improvement in the signal-to-noise ratio can be achieved by adding up a multitude of the spectrum recorded with the mass spectrometer. The time resolution of the overall system is a product of the frequency with which the spectra are transferred to the evaluation. This frequency may be between 0.1 Hz and 100 Hz. This is a distinct improvement over existing systems in which several minutes are required for recording of a single spectrum over the measurement range of 1 to 200 daltons.

The residual gas analyser may include a filter unit in order to filter out ionized constituents having a particular mass/charge ratio. The filter device can filter ions still present on entry into the filter device out of the stream of ions, such that they cannot make any contribution to the mass spectrometry analysis. In particular, constituents that are ionized with the filter device and are present in high density in the stream of ions may be filtered out in order to increase the dynamic range of the mass spectrometer. Constituents that are frequently present in high concentration in the residual gas are, for example, hydrogen (H₂) or nitrogen (N₂).

The filter units may take the form of a quadrupole. By applying a suitable AC field, the quadrupole can be adjusted such that particular constituents of the residual gas are filtered out and consequently make no contribution to the mass spectrometry analysis. The filter unit may be disposed between the ion source and the mass spectrometer. The filter unit may be connected to the mass spectrometer to form a common component.

Also of interest in other embodiments of the disclosed techniques is the detection of those constituents of the residual gas that are electrically neutral but are highly reactive owing to excited electronic states. Such constituents frequently lose reactivity on the way between the vacuum environment and the mass spectrometer owing to impacts with components of the residual gas analyser.

The disclosed techniques encompass the idea of detecting such excited constituents of the residual gas by putting the constituents in an ionized state. Since the original state is already an excited electronic state, a smaller amount of energy supplied is sufficient for ionization.

In one embodiment, the ion source includes an ionization unit that ionizes neutral constituents of the residual gas via an electrical field. The electrical field may be adjusted such that hydrogen constituents of the residual gas, such as H₂, H₃, inter alia are ionized. The ionized hydrogen constituents can convert other neutral constituents, for example N₂H⁺ or H₃O⁺, to an ionized state.

The ion source may include an electrical conductor that extends around the ionization volume. The ionization volume refers to the volume in which there are ionizations as a result of the effect of the ionization unit. In particular, the conductor may extend along a helical pathway around the ionization volume. Flow of current in the electrical conductor can result in generation of electrical field in the ionization volume, which is sufficient to bring about field ionization.

The electrical conductor may be operated at low power, for example at a power between 0.2 W and 5 W, preferably between 0.5 W and 2 W. It has been found that such a power is sufficient to generate an electrical field of sufficient strength for field ionization, while, on the other hand, electromagnetic radiation that disrupts the projection exposure apparatus can be avoided. The electrical conductor may be fed with an electrical signal that has a frequency between 10 MHz and 20 MHz.

In order to avoid loss of the activity of the excited constituents, it is advantageous when the ion source is disposed close to the receptacle. Conversely, proximity between ion source and receptacle has the disadvantage that the residual gas in the receptacle can be contaminated by material removed by components of the ion source. It is therefore favorable when the ion source is configured such that no materials that are expected to remove material come into contact with the residual gas atmosphere. In particular, the ion source may be free of electrodes that come into contact with the residual gas atmosphere.

The electrical conductor of the ion source may be constructed from, for example, a ceramic material. A dividing wall may be formed between the electrical conductor and the ionization volume. The dividing wall may consist of a dielectric material. In one embodiment, the dividing wall consists of glass. Both ceramic and glass are materials that withstand the atmosphere that exists in the vacuum environment without troublesome removal of material. Materials having equal resistance to the conditions that exist in the vacuum environment may likewise be used. The electrical conductor may be fed with a single wire, which facilitates connection outward.

The ion source may be surrounded by a shielding housing. This is in order to prevent disruptive electromagnetic radiation from spreading into the environment. The shielding housing may be formed by a tubular metal housing. In one embodiment, the shielding housing is formed by a vacuum flange in a standardized size, for example a CF40 adapter flange.

The ion source may have an inlet opening through which the constituents of the residual gas pass when the residual gas enters the ionization volume from the vacuum environment. The ion source may have an outlet opening through which the constituents of the residual gas pass when leaving the ion source. The shielding housing may include a shield of the inlet opening, such that electromagnetic radiation is prevented from exiting through the inlet opening. The shielding housing may include a shield of the outlet opening, such that electromagnetic radiation is prevented from exiting through the outlet opening.

In the first switching state of the ion source, the ionization unit is active, such that constituents of the residual gas present in the ionization volume are ionized. In the second switching state of the ion source, the ionization unit is inactive, such that constituents of the residual gas present in the ionization volume are not subjected to any ionizing influence. The constituents of the residual gas may pass freely through the ion source. The ionization volume may form a freely passable channel for the constituents of the residual gas.

An ion transfer unit may be disposed between the ion source and the mass spectrometer. The ion transfer unit may have one or more of the above mentioned features of an ion transfer unit.

The residual gas analyser may include a control unit (or controller) designed to actuate the components of the residual gas analyser. The control unit can direct control commands to the ion source, with which the ion source is switched between the first switching state and the second switching state. The control unit may be designed to record a mass spectrum ascertained with the mass analyser in a memory unit such that assignment between the measured mass spectrum and the corresponding switching state of ion source is assured. The switching time for the switching between the first switching state and the second switching state may be less than 1 s, such that a change between the two modes of operation of the residual gas analyser is possible at short notice at any time.

The disclosed techniques also relate to a microlithography projection exposure apparatus equipped with such a residual gas analyser. The projection exposure apparatus may include a radiation source that emits very short-wave UV radiation. Very short-wave UV radiation includes DUV radiation in the deep ultraviolet spectral region with wavelengths between 100 nm and 300 nm and EUV radiation in the extreme ultraviolet spectral region with wavelengths between 5 nm and 100 nm, especially with wavelengths between 5 nm and 30 nm. The projection exposure apparatus may include an exposure system and a projection lens, wherein the exposure system directs the very short-wave UV radiation onto an object field in an object plane, and wherein the projection lens images the object field into an image plane. The projection exposure system may include a multitude of optical elements with which the very short-wave UV radiation is directed along an exposure beam path to the image plane. The optical elements may take the form of reflective optical elements.

The optical components of the projected exposure system may be enclosed in a vacuum housing. The projection exposure system may include a vacuum pump connected to the vacuum housing, which is designed to generate a high vacuum in the vacuum housing. The pressure of the high vacuum may, for example, be between 10⁻⁷ and 10⁻⁸ mbar.

An inner housing may be formed within the vacuum housing. The inner housing may wholly or partly enclose sections of the exposure beam path and/or one or more optical elements, such that a micro-environment is formed within the vacuum housing. The inner housing need not be impervious in a macroscopic sense. Under high vacuum conditions in the vacuum housing, an inner housing which is not impervious in a macroscopic sense may be sufficient to create a distinctly different atmosphere within the micro-environment than in the rest of the vacuum housing.

The inner housing may be provided with a connection for a purge gas, such that an atmosphere different from the rest of the vacuum housing can be applied in the micro-environment. The pressure in the micro-environment may be in the fine vacuum region, for example between 10⁻¹ mbar and 10⁻³ mbar. The purge gas may be hydrogen (H₂), which serves to remove contamination from the micro-environment and especially from the mirror surfaces present therein. The atmosphere in the inner housing may be formed by the residual gas which is examined by the residual gas analyser according to the disclosed techniques.

An inlet opening for the residual gas analyser may be disposed in the inner housing, such that the residual gas can enter the residual gas analyser from the micro-environment. The mass spectrometer may be disposed outside the vacuum housing. The switchable ion source may be disposed within or outside the vacuum housing. The path taken by the ions between the micro-environment and the mass spectrometer may extend within a vacuum tube. A vacuum tube refers to a housing wall that separates an interior enclosed by the housing wall from the atmosphere in the vacuum housing. The term “vacuum tube” does not imply any restriction to a particular structure or shape of the housing wall. Free mass transfer may exist between the interior of the vacuum tube and the micro-environment, such that the atmosphere in the vacuum tube corresponds essentially to the atmosphere in the micro-environment. The predominant portion of the distance between the wall of the inner housing and the wall of the vacuum housing may be occupied by the ion transfer unit. For example, the ion transfer unit may extend at least 50%, preferably at least 70%, further preferably at least 90%, of this distance.

The disclosed techniques also relate to a method of residual gas analysis, especially of a residual gas in a microlithography projection exposure apparatus. In the method, constituents of the residual gas are directed from a vacuum environment into a mass spectrometer. Disposed between the vacuum environment and the mass spectrometer is an ion source that allows constituents of the residual gas that have been ionized to pass through in a first switching state, and ionizes neutral constituents of residual gas in a second switching state. The ion source is switched between the first switching state and the second switching state. Mass spectra are recorded for the first switching state and the second switching state.

This disclosure encompasses developments of the method with features that are described in the context of the residual gas analyser according to the disclosed techniques. The disclosure encompasses developments of the residual gas analyser with features that are described in the context of the method according to the disclosed techniques.

### BRIEF DESCRIPTION OF THE DRAWINGS

The invention is described by way of example hereinafter using advantageous embodiments, with reference to the appended drawings. The figures show:

FIG. 1: an embodiment of a projection exposure apparatus according to the disclosed techniques;

FIG. 2: an embodiment of a residual gas analyser according to the disclosed techniques;

FIG. 3: the ion decelerator from FIG. 2 in an enlarged schematic diagram;

FIG. 4: a mass spectrum recorded with a residual gas analyser according to the disclosed techniques;

FIG. 5: a mass spectrum recorded without a low-mass filter;

FIG. 6: a mass spectrum recorded with a low-mass filter;

FIG. 7: a schematic diagram of the ion source from FIG. 2 in a first switching state;

FIG. 8: a schematic diagram of the ion source from FIG. 2 in a second switching state;

FIG. 9: an alternative embodiment of a residual gas analyser according to the disclosed techniques;

FIG. 10: a schematic diagram of the ion source from FIG. 9;

FIG. 11: a mass spectrum recorded with the residual gas analyser from FIG. 9.

### DETAILED DESCRIPTION

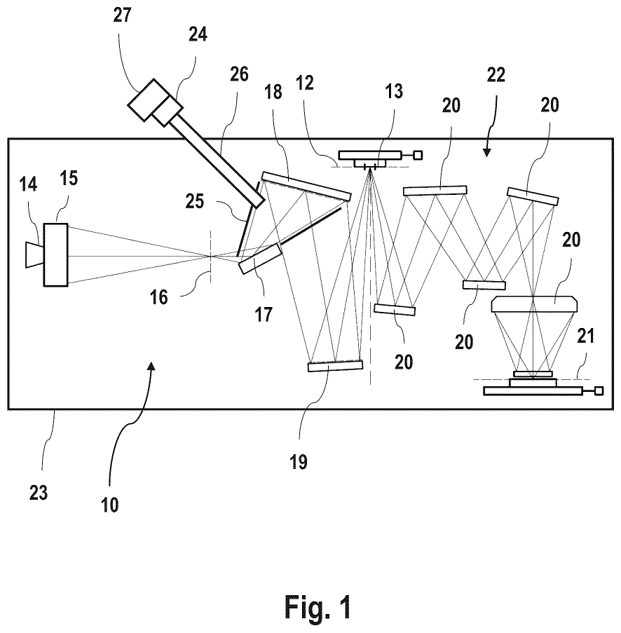

FIG. 1 shows a schematic of a microlithography EUV projection exposure apparatus. The projection exposure apparatus includes an exposure system 10 and a projection lens 22. The illumination system 10 exposes an object field 13 in an object plane 12. The projection lens 22 serves to image the object field 13 into an image plane 21.

The illumination system 10 includes an exposure radiation source 14 which emits electromagnetic radiation in the EUV range, i.e., with a wavelength of between 5 nm and 30 nm in particular. The EUV radiation emanating from the exposure radiation source 14 is first focused into an intermediate focus plane 16 with a collector 15.

A deflecting mirror 17 deflects the EUV radiation onto a first facet mirror 18. The first facet mirror 18 is followed by a second facet mirror 19, with which the individual facets of the first facet mirror 18 are imaged into the object field 13.

With the aid of the projection lens 22, the object field 13 is imaged into an image plane 21 using a multitude of mirrors 20. Disposed in the object field 13 is a mask (also called reticle) which is imaged onto a light-sensitive layer of a wafer disposed in the image plane 21.

The various mirrors of the projection exposure apparatus at which the illumination radiation is reflected take the form of EUV mirrors. The EUV mirrors have been provided with highly reflective coatings. These may be multilayer coatings, especially multilayer coatings having alternating layers of molybdenum and silicon.

The components of the projection exposure apparatus are disposed in a vacuum housing 23. The interior of the vacuum housing 23, in operation of the projection exposure apparatus, is put under high vacuum with a vacuum pump (not shown) at a pressure of, for example, 10⁻⁸ mbar. Formed in the interior of the vacuum housing 23 is an inner housing 25 that surrounds the exposure beam path.

FIG. 1 indicates merely a section of the inner housing 25 disposed between the deflecting mirror 17 and the first facet mirror 18. In fact, the housing 25 surrounds further sections of the beam pathway. The inner housing 25 is configured such that the exposure beam pathway can take its path across the various optical elements 17, 18, 19, 20, without the inner housing 25 being in the way.

The inner housing 25 is not impervious in the macroscopic sense with respect to the remainder of the interior of the vacuum housing 23. For example, gaps that may be formed between the inner housing 25 and optical elements 17, 18, 19, 20, at which the exposure beam path is reflected, permit mechanical adjustment of the optical elements. Nevertheless, the inner housing 25, under the high-vacuum conditions that exist in the vacuum housing 23, enables an atmosphere in the interior of the inner housing 25 which is distinctly different from the atmosphere in the rest of the vacuum housing 23.

The projection exposure apparatus includes a purge gas connection (not shown in FIG. 1) via which hydrogen is fed into the inner housing 25, such that there is a partial hydrogen pressure in the order of magnitude of 10⁻² mbar in the interior of the inner housing 25.

Interaction between the EUV radiation and the hydrogen creates a plasma, forming ionic plasma species (H⁺) or free-radical plasma species (H) inter alia. The hydrogen plasma has the effect that contamination is removed from surfaces of the optical elements disposed in the inner housing 25. This gives rise to compounds, for example, of hydrogen and carbon or of hydrogen and nitrogen that are distributed in the residual gas atmosphere in the interior of the inner housing 25.

The residual gas analyser 24 according to the disclosed techniques has the purpose of obtaining information about the composition of the residual gas in the interior of the inner housing 25. Species of interest are both ionic species present in the residual gas atmosphere and neutral species present in the residual gas atmosphere. FIG. 1 shows a single residual gas analyser 24 connected to the inner housing 25 in the region between the deflecting mirror 17 and the first facet mirror 18. The projected exposure apparatus may include a multitude of residual gas analysers 24 in order to be able to analyse the composition of the residual gas in various regions of the inner housing 25.

The residual gas analyser 24 includes a vacuum tube 26 that extends outward from the interior of the inner housing 25 through the wall of the vacuum housing 23. The length of the vacuum tube 26 is on the order of magnitude of 80 cm. The vacuum tube 26 has an inlet opening disposed in the inner housing 25, such that exchange of gas takes place between the residual gas atmosphere in the inner housing 25 and the interior of the vacuum tube 26. The vacuum tube 26 is sealed with respect to the interior of the vacuum housing 23.

The constituents of the residual gas are directed through the vacuum tube 26 to a mass spectrometer 27 disposed outside the vacuum housing 23, where they are analysed for their ratio of mass to charge.

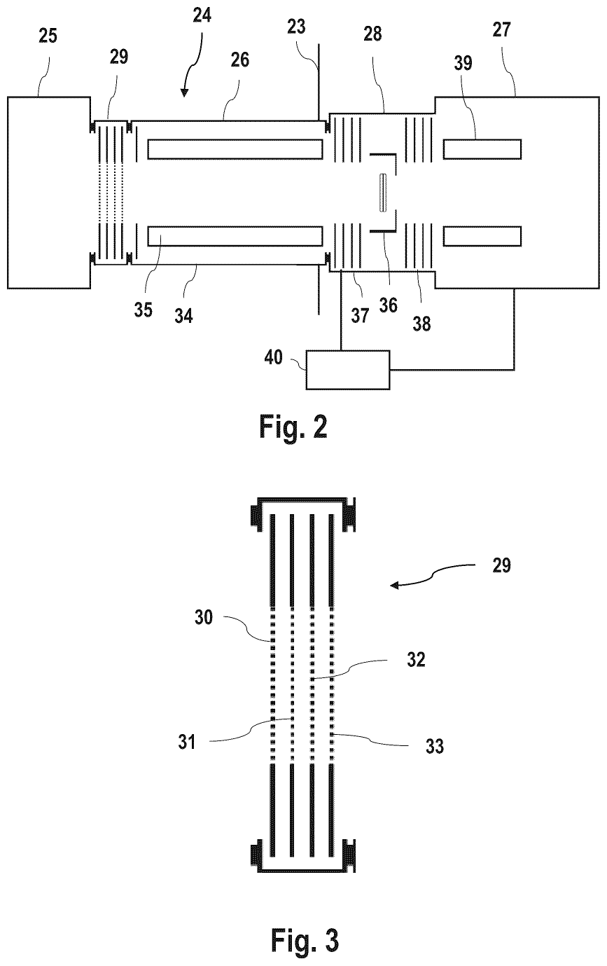

According to FIG. 2, the residual gas analyser 24, within the vacuum tube 26, has an ion decelerator 29 and an ion transfer unit 34. A switchable ion source 28 and a mass spectrometer 27 are disposed outside the vacuum housing 23. In a first mode of operation of the residual gas analyser 24, the ion source 28 is in a first switching state in which ionic species are directed through the ion source 28 to the mass spectrometer. The ion decelerator 29 and the ion transfer unit 34 are intended for the first mode of operation of the residual gas analyser 24 and serve to supply the ion source 28 with native ions from the residual gas. In a second mode of operation of the residual gas analyser 24, the ion source 28 is in a second switching state in which neutral constituents of the residual gas are neutralized. The neutral constituents of the residual gas penetrate as far as the ion source 28 through free gas exchange. The ion decelerator 29 and the ion transfer unit 30 have no function in the second mode of operation of the residual gas analyser 24.

First of all, the mode of functioning of the residual gas analyser 24 in the first mode of operation will be outlined. The ion decelerator 29 is disposed adjacent to the inlet opening of the vacuum tube 26, such that native ions that pass into the vacuum tube 26 go in high number into the region of influence of the ion decelerator 29, without being neutralized beforehand by contact with other components of the residual gas analyser 24. The ion decelerator 29, according to FIG. 3, includes four grids 30, 31, 32, 33, arranged successively in the direction of movement of the ionic species. A deceleration voltage is applied to the grids, such that native ions are decelerated as they pass through the ion decelerator 29. Only ionic species having sufficiently high kinetic energy upon entry into the ion decelerator 29 overcome the deceleration voltage and penetrate as far as the outlet from the ion decelerator 29.

The ion decelerator 29 has a length of a few centimetres, and so a considerable distance within the vacuum tube 26 still has to be covered before the composition of the native ions can be examined by the mass spectrometer 27. The native ions are conducted onward through the vacuum tube 26 via the ion transfer unit 34. The ion transfer unit 34 includes a hexapole 35 that extends in the direction of movement of the native ions. The hexapole 35 is formed by six poles distributed uniformly over the circumference of the ion transfer unit 34, which are alternately at a positive or negative potential. In addition to an AC voltage, it is also possible to apply a DC bias to the hexapole 35, such that the native ions retain their preferential direction. The hexapole 35 acts as ion optics, with which the ionic species are concentrated to an ion beam that moves along the central axis of the hexapole 35. FIG. 2 shows a single hexapole 35 that extends over the entire length of the ion transfer unit 34. Alternatively, multiple hexapoles 35 may be arranged successively in longitudinal direction of the ion transfer unit 34.

Since uncharged species can pass through the ion decelerator 29 unhindered, there is an atmosphere with a high proportion of hydrogen in the region of the ion transfer unit 34, similar to that in the inner housing 25. Impacts with the hydrogen constituents result in deceleration of the ionic species, such that the kinetic energy of the ionic species corresponds essentially to thermal movement at the outlet from the ion transfer unit 34. This means that the ionic species at the outlet from the ion transfer unit 34 have a defined state, which creates a favorable starting point for the subsequent mass spectrometry analysis.

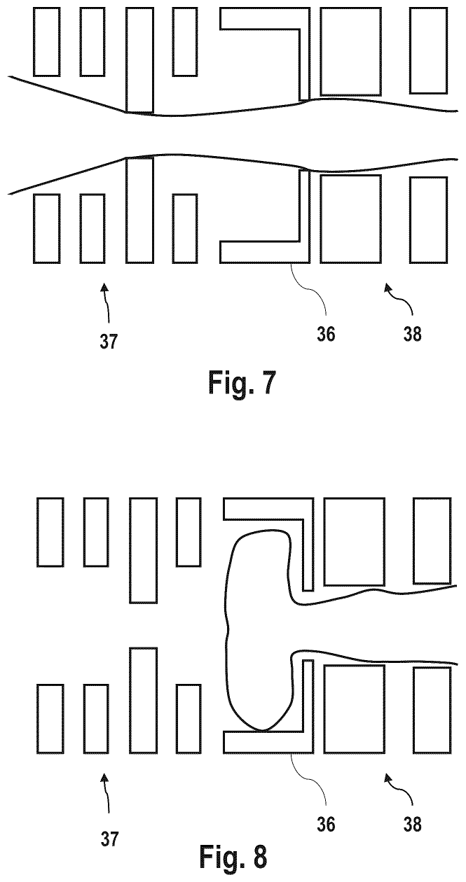

The switchable ion source 28 disposed outside the vacuum housing 23 follows on from the end of the vacuum tube 26. In the first mode of operation of the residual gas analyser 24, the switchable ion source 28 acts as ion optics, with which the ions passing across from the ion transfer unit 34 are focused on to the inlet of the mass spectrometer 27; see FIG. 7. The ion optics are formed by a first electrode arrangement 37 and a second electrode arrangement 38, which are suitably actuated by electrical signals.

The ion source 28 further includes an ionization unit 36 which is designed to ionize neutral constituents of the residual gas. In the first mode of operation of the residual gas analyser 24, the ionization unit 36 is inactive, such that the ions coming from the ion transfer unit 34 can pass through the ion source 28 unaffected by ionization unit 36.

In the second mode of operation, the residual gas analyser 24 is utilized in order to analyse neutral constituents of the residual gas that have arrived at the switchable ion source 28 from the inner housing 25 via free gas exchange. The ionization unit 36 is active in that a filament of the ionization unit 36 is supplied with electrical power, such that electrons are released by thermionic emission. By application of a voltage, these are accelerated through an ionization volume disposed within the ionization unit 36, such that neutral constituents of the residual gas are ionized; see FIG. 8. The first electrode arrangement 37 is actuated such that the native ions are blocked and cannot penetrate as far as the ionization volume. The ion decelerator 29 and the ion transfer unit 34 play no role in the second mode of operation.

The mass spectrometer 27 may also take the form of a time-of-flight mass analyser (TOF analyser), especially of a time-of-flight mass analyser with an orthogonal acceleration stage. The mass spectrometer 27 may have a measurement range of 1 to 500 daltons, such that complete mass spectra can be recorded over this mass range. The recording frequency of the mass spectrometer may be greater than 10 kHz. Addition of the spectra can achieve a distinct improvement in the signal-to-noise ratio.

The time resolution of the overall system is a product of the frequency with which the spectra are transferred to the evaluation. This frequency may be between 0.1 Hz and 100 Hz. This is a distinct improvement over existing systems in which several minutes are required for recording of a single spectrum over the measurement range of 1 to 200 daltons.

The inlet of the mass spectrometer 27 is formed by a quadrupole 39. The quadrupole 39 can filter out ions that enter the mass spectrometer 27 in high density, in order thus to increase the dynamic range of the mass spectrometer. In particular, it is possible to specifically filter individual constituents of the residual gas that have a particular mass-to-charge ratio, for example the hydrogen (H₂) or nitrogen (N₂) constituents that are frequently present with a high partial pressure. By applying a suitable AC field, the quadrupole 39 can be adjusted such that particular constituents of the residual gas are filtered out and consequently make no contribution to the mass spectrometry analysis.

The residual gas analyser 24 includes a control unit (or controller) 40 that controls the interplay of the components of the residual gas analyser 24. The control unit 40 sends control commands to the ion source 28 in order to switch the ion source 28 between the first switching state and the second switching state. The control unit 40 stores the mass spectra obtained with the mass spectrometer 27 in such a way that there is assignment between the mass spectra and the respective switching state of the ion source 28. The switching time for the switching between the first switching state and the second switching state is less than 1 s, such that a change between the two modes of operation of the residual gas analyser is possible at short notice at any time.

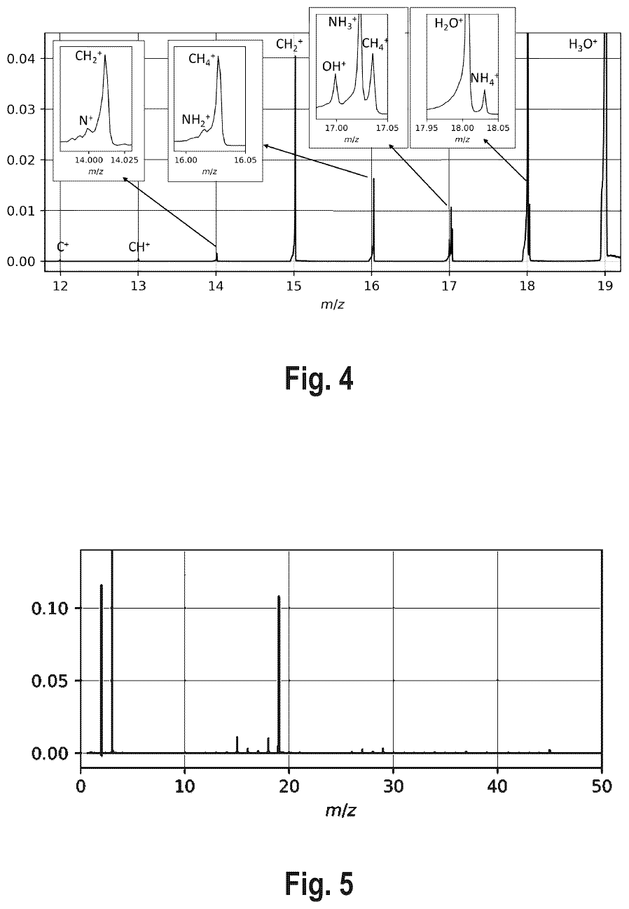

FIG. 4 shows a mass spectrum generated with the residual gas analyser 24. Plotted on the horizontal axis is the ratio of mass to charge m/z, and on the vertical axis the intensity in normalized units. What is shown is the very good resolution that can be achieved with the residual gas analyser according to the disclosed techniques because of the defined state of the ionic species on entry into the mass spectrometer 27. For instance, at about 17 daltons, the ionic species OH⁺, NH₃⁺ and CH₄⁺ form three distinctly separated peaks. The same applies to the peaks of H₂O⁺ and NH₄⁺ close to 18 daltons. In conventional methods, these peaks vanish within a broader distribution.

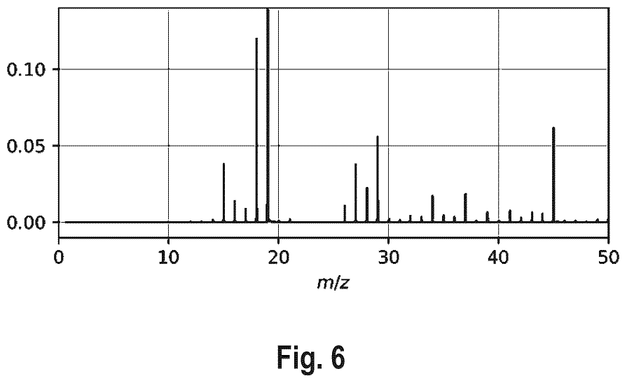

FIG. 5 shows a corresponding mass spectrum which is saturated at 3 daltons (H₃⁺). The mass spectrum was recorded with an RF voltage of 21 V at the quadrupole 39, a consequence of which is that the H₃⁺ species pass through the quadrupole filter in a large number. For comparison, FIG. 6 shows a mass spectrum in which there is an RF voltage of 230 V at the quadrupole 39, as a result of which the H₃⁺ species are effectively filtered out, such that they play no role in respect of the mass spectrometry analysis. The signal is now saturated at 19 daltons (H₃O⁺), which results in a significant increase in the dynamic range of analysis.

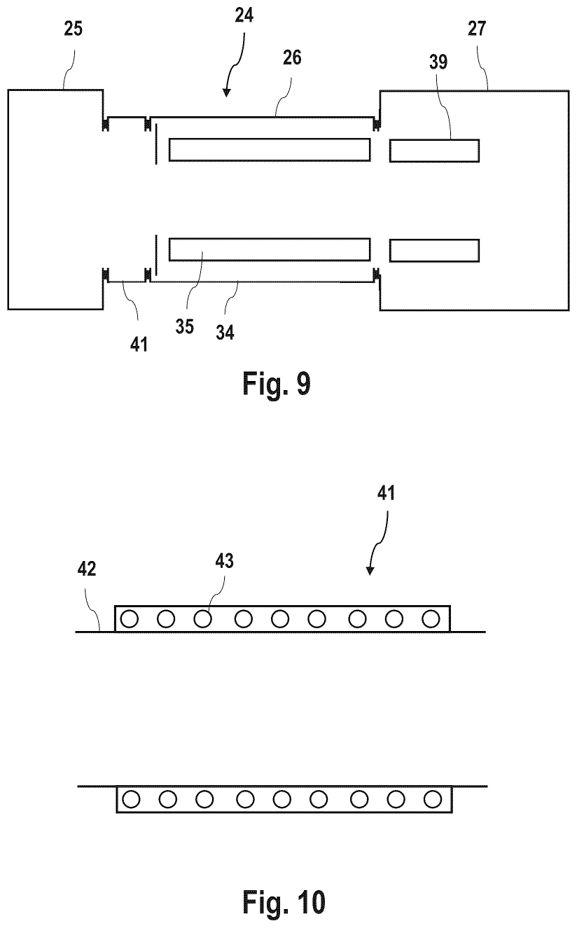

FIG. 9 shows an alternative embodiment of a residual gas analyser 24 according to the disclosed techniques, in which the switchable ion source 41 is disposed between the inner housing 25 and the ion transfer unit 34. The ion source 41, according to FIG. 10, includes an ionization unit which is formed by a glass tube 42 and a helical conductor 43 made of a ceramic material that surrounds the glass tube 42. The glass tube 42 encloses a central channel aligned with the ion transfer unit 34. The central channel forms the ionization volume of the ionization unit. Glass and ceramic are materials that are free of removal of material under the given conditions, e.g., material is not ejected/emitted therefrom under that gas pressures present in the device, such that impurities in the residual gas atmosphere are avoided.

In the first switching state, the ion source 41 is inactive, such that constituents of the residual gas can pass unhindered through the ion source 41 and can penetrate as far as the mass spectrometer 27 through free gas exchange. The mass spectrometry analysis may be conducted as described above.

In the second switching state, an electrical voltage is applied to the conductor 43, such that it acts as helical resonator. Neutral constituents of the residual gas that are already in an excited state are ionized by field ionization. The ionized species penetrate as far as the inlet side of the ion transfer unit 34, where they are passed onward as described above to the mass spectrometer 27, where the ionized species are analysed by mass-charge ratio.

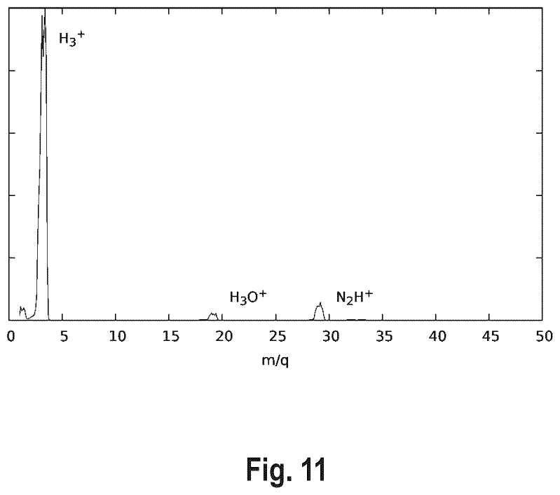

FIG. 11 shows a mass spectrum of a helical resonator plasma in hydrogen that has been recorded with this residual gas analyser. Since hydrogen is the main constituent present, the plasma is dominated by charge carriers such as H₂⁺ and H₃⁺. Both are capable of ionizing other neutral species in the trace region by charge transfer, which can be seen from the additional signals of nitrogen (N₂H⁺) and water (H₃O⁺).

What is claimed is:

1. A residual gas analyser, comprising:
a mass spectrometer; and
an admission device configured to admit constituents of a residual gas from a vacuum environment into the mass spectrometer, the admission device comprising a switchable ion source configured to switch between a first switching state that allows ionized constituents of the residual gas to pass through the admission device and a second switching state that ionizes neutral constituents of the residual gas.

2. The residual gas analyser of claim 1, wherein the vacuum environment comprises a vacuum environment of a microlithography projection exposure apparatus.

3. The residual gas analyser of claim 1, wherein the switchable ion source comprises an ionizer designed to ionize constituents of the residual gas by electrical interaction.

4. The residual gas analyser of claim 3, wherein the switchable ion source comprises a first electrode arrangement and a second electrode arrangement, wherein the first electrode arrangement is disposed between an inlet opening of the switchable ion source and the ionizer, and wherein the second electrode arrangement is disposed between the ionizer and an outlet opening of the switchable ion source.

5. The residual gas analyser of claim 4, wherein, in the first switching state, the first electrode arrangement and the second electrode arrangement collectively form ion optics for ions that enter the switchable ion source.

6. The residual gas analyser of claim 4, wherein, in the second switching state, the first electrode arrangement and/or second electrode arrangement is actuated such that native ions are blocked.

7. The residual gas analyser of claim 1, wherein the admission device comprises an ion transfer device disposed between an inlet opening of the residual gas analyser and the mass spectrometer.

8. The residual gas analyser of claim 7, wherein the ion transfer device extends over a distance of at least 20 cm.

9. The residual gas analyser of claim 8, wherein the ion transfer device extends over a distance of at least 50 cm.

10. The residual gas analyser of claim 8, wherein the ion transfer device extends over a distance of at least 80 cm.

11. The residual gas analyser of claim 7, wherein an ion decelerator is disposed between the inlet opening of the residual gas analyser and the ion transfer device in order to slow down native ions entering the residual gas analyser with an adjustable deceleration voltage.

12. The residual gas analyser of claim 1, wherein the switchable ion source comprises an ionizer that ionizes neutral constituents of the residual gas by an electrical field.

13. The residual gas analyser of claim 12, wherein the ionizer comprises an electrical conductor made of a ceramic material.

14. The residual gas analyser of claim 12, wherein an ion transfer device is disposed between the switchable ion source and the mass spectrometer.

15. The residual gas analyser of claim 1, wherein the mass spectrometer comprises a time-of-flight mass analyser, especially of a time-of-flight mass analyser with an orthogonal acceleration stage.

16. The residual gas analyser of claim 1, having a controller in order to actuate the switchable ion source, such that the switchable ion source is switched between the first switching state and the second switching state.

17. A projection exposure apparatus, comprising:
a radiation source for emitting very short-wave UV radiation;
a vacuum housing;
a plurality of optical elements arranged within the vacuum housing and configured to guide the very short-wave UV radiation emitted by the radiation source along an exposure beam pathway into an image plane; and
a residual gas analyser according to claim 1.

18. The projection exposure apparatus of claim 17, further comprising an inner housing formed within the vacuum housing, wherein an atmosphere within the inner housing differs from an atmosphere of the vacuum housing outside the inner housing, and wherein an inlet opening of the residual gas analyser is disposed in the inner housing.

19. A method of residual gas analysis, especially for a residual gas in a microlithography projection exposure apparatus, comprising:
directing constituents of residual gas from a vacuum environment into a mass spectrometer;
ionizing the constituents of the residual gas via an ion source disposed between the vacuum environment and the mass spectrometer, wherein the ion source allows ionized constituents of residual gas to pass through in a first switching state and ionizes neutral constituents of the residual gas in a second switching state;
switching the ion source between the first switching state and the second switching state; and
recording mass spectra for the first switching state and the second switching state.
